(19) United States
(12) Patent Application Publication
(10) Pub. No.: US 2026/0290761 A1
(43) Pub. Date: Sep. 24, 2026

(54) COVER AND PLASMA PROCESSING APPARATUS

(71) Applicant: Tokyo Electron Limited, Tokyo (JP)

(72) Inventor: Kazushi KANEKO, Nirasaki City (JP)

(21) Appl. No.: 19/561,868

(22) Filed: Mar. 10, 2026

(30) Foreign Application Priority Data
Mar. 19, 2025 (JP) 2025-044339

(51) Int. Cl. H01J 37/32

(52) U.S. Cl. CPC H01J 37/32651; H01J 37/3211; H01J 2237/0266

(57) ABSTRACT

A cover that prevents electromagnetic wave leakage from a coil-shaped antenna provided in a plasma processing apparatus, the cover including: a metallic frame body; and a plurality of segments provided on an inner surface of the frame body, wherein the plurality of segments are configured to cover the inner surface with a gap between each of the plurality of segments.

### CROSS-REFERENCE TO RELATED APPLICATION

This application is based upon and claims the benefit of priority from Japanese Patent Application No. 2025-044339, filed on Mar. 19, 2025, the entire contents of which are incorporated herein by reference.

### TECHNICAL FIELD

The present disclosure relates to a cover and a plasma processing apparatus.

### BACKGROUND

Patent Document 1 discloses that “there is provided a plasma processing apparatus that performs a predetermined plasma processing on a processing target substrate by generating an inductively coupled plasma of a processing gas in a depressurized processing chamber. The plasma processing apparatus includes a stage in the processing chamber to place the processing target substrate thereon, a gas supplier configured to introduce the processing gas into the processing chamber, an exhauster configured to evacuate and depressurize the processing chamber, a planar radio frequency antenna disposed to face the stage with a plate-shaped dielectric interposed therebetween, a shield provided to cover the radio frequency antenna, and a radio frequency power supply configured to apply a radio frequency power to the radio frequency antenna to generate the inductively coupled plasma between the plate-shaped dielectric and the stage. The radio frequency antenna is composed of an antenna element configured to open both ends, ground a midpoint or a vicinity, and resonate with half wavelength of the radio frequency power from the radio frequency power supply”.

### PRIOR ART DOCUMENTS

### Patent Documents

Patent Document 1: Japanese Patent Laid-open Publication No. 2010-153274

### SUMMARY

According to one embodiment of the present disclosure, a cover, which prevents leakage of electromagnetic waves from a coil-shaped antenna provided in a plasma processing apparatus, includes a metallic frame body and a plurality of segments provided on an inner surface of the frame body. The plurality of segments are configured to cover the inner surface with a gap between each of the plurality of segments.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view illustrating an exemplary configuration of a plasma processing apparatus according to an embodiment of the present disclosure.

FIG. 2 is a diagram illustrating an exemplary relationship between resistor thickness, skin depth, and physical property values.

FIG. 3 is a diagram illustrating an exemplary a relationship between heat generation, physical property values, and shape of a resistor.

FIG. 4 is a diagram illustrating an exemplary segment.

FIG. 5 is a plan view illustrating an exemplary configuration, as viewed from below, of a first layer of a two-layer resistor film in a cover according to the present embodiment.

FIG. 6 is a plan view illustrating an exemplary configuration, as viewed from below, of a second layer of a two-layer resistor film in a cover according to the present embodiment.

FIG. 7 is a cross-sectional view illustrating an exemplary a cross-section of a cover according to the present embodiment.

FIG. 8 is a plan view illustrating an exemplary configuration, as viewed from below, of a third layer of a four-layer resistor film in a cover according to the present embodiment.

FIG. 9 is a plan view illustrating an exemplary configuration, as viewed from below, of a fourth layer of a four-layer resistor film in a cover according to the present embodiment.

FIG. 10 is a cross-sectional view illustrating another exemplary cross-section of a cover according to the present embodiment.

FIGS. 11A to 11C are diagrams illustrating exemplary arrangements of a plurality of segments according to the present embodiment.

FIG. 12 is a diagram illustrating an exemplary relationship between electromagnetic wave frequency and power loss.

FIG. 13 is a diagram illustrating an exemplary relationship between electromagnetic wave frequency and skin depth.

FIG. 14 is a diagram illustrating an exemplary relationship between physical property values and skin depth.

FIG. 15 is a diagram illustrating an exemplary relationship between physical property values and power loss.

FIG. 16 is a diagram illustrating an exemplary setting of physical property values and segment size.

FIG. 17 is a diagram illustrating another exemplary setting of physical property values and segment size.

FIG. 18 is a diagram illustrating another exemplary setting of physical property values and segment size.

FIG. 19 is a diagram illustrating an exemplary normalized loss at a specific frequency.

FIG. 20 is a diagram illustrating an exemplary loss setting for each frequency.

FIG. 21 is a diagram illustrating another exemplary setting of physical property values and segment size.

FIG. 22 is a diagram illustrating another exemplary setting of physical property values and segment size.

FIG. 23 is a diagram illustrating an exemplary an application range based on loss setting and segment size.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a cover and a plasma processing apparatus disclosed herein will be described in detail with reference to the accompanying drawings. In addition, the disclosed technique is not limited by the following embodiments.

In an inductively coupled plasma processing apparatus, to prevent electromagnetic wave leakage to the outside of the apparatus, for example, a metallic cover is provided to cover a coil-shaped antenna. However, when the distance between the metallic cover and the coil-shaped antenna is small, the metallic cover is easy to couple with the coil-shaped antenna, resulting in eddy currents. Therefore, electromagnetic waves supplied from the coil-shaped antenna generate eddy currents in the metallic cover, thereby increasing power loss due to heat generation. Further, when attempting to prevent eddy currents, it is required to increase the distance between the metallic cover and the coil-shaped antenna. Accordingly, it is desired to increase power contributing to plasma generation by reducing eddy currents, while decreasing the distance between the metallic cover and the coil-shaped antenna.

### [Configuration of Plasma Processing Apparatus]

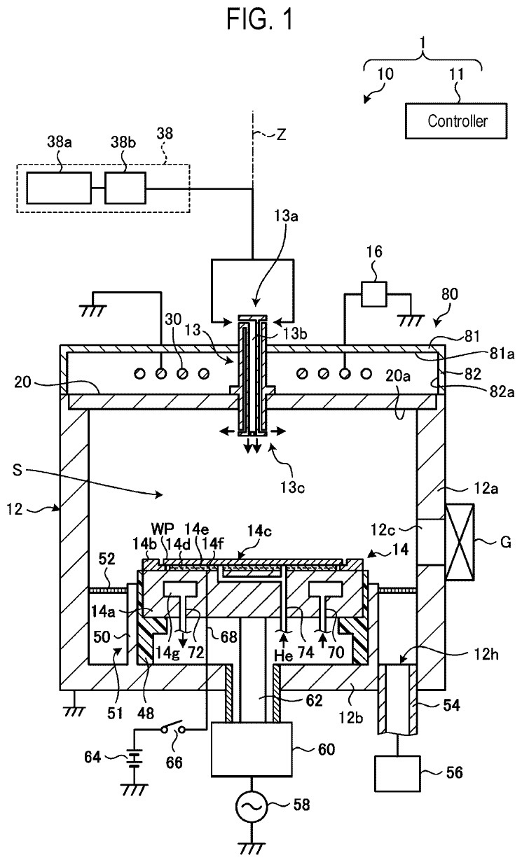

FIG. 1 is a schematic cross-sectional view illustrating an exemplary configuration of a plasma processing apparatus according to an embodiment of the present disclosure. The plasma processing apparatus 1 includes an apparatus main body 10 and a controller 11. The apparatus main body 10 includes a processing container 12, a stage 14, a radio frequency (RF) power supply (an example of an electromagnetic wave generator) 16, a dielectric window 20, an antenna 30, and a gas supplier 38. Further, the apparatus main body 10 includes a central gas injector 13. The central gas injector 13 is disposed above the stage 14 and is attached to a central opening of the dielectric window 20. The antenna 30 is disposed on or above (outside) the processing container 12 (dielectric window 20). The antenna 30 is covered by a cover 80 from above and from the lateral side.

The processing container 12 is formed in a substantially cylindrical shape using, for example, aluminum having an anodized surface, and provides a substantially cylindrical processing space S in the interior thereof. The processing container 12 is securely grounded. Further, the processing container 12 includes a sidewall 12a and a bottom 12b. A central axis of the sidewall 12a is defined as an axis Z. The bottom 12b is provided at a lower end of the sidewall 12a. An exhaust port 12h for evacuation is provided in the bottom 12b. Further, an upper end portion of the sidewall 12a is open. Further, an inner wall surface of the sidewall 12a faces the processing space S. That is, the sidewall 12a is provided so that the inner wall surface faces the processing space S.

An opening 12c is formed in the sidewall 12a to load/unload a substrate WP. The opening 12c is opened and closed by a gate valve G.

The dielectric window 20 is provided at the upper end portion of the sidewall 12a, and closes an opening at the upper end portion of the sidewall 12a from above. A lower surface 20a of the dielectric window 20 faces the processing space S. That is, the dielectric window 20 is provided so that the lower surface 20a faces the processing space S.

The stage 14 is accommodated in the processing container 12. The stage 14 is provided to face the dielectric window 20 in the direction of the axis Z. A space between the stage 14 and the dielectric window 20 is the processing space S. The substrate WP is placed on the stage 14. That is, the stage 14 is an example of a substrate support configured to support the substrate WP in the processing container 12.

The stage 14 includes a base 14a and an electrostatic chuck 14c. The base 14a is formed in a substantially disk shape using a conductive material such as aluminum. The base 14a is arranged in the processing container 12 such that a central axis of the base 14a substantially coincides with the axis Z.

The base 14a is supported by a cylindrical support 48, which is made of an insulating material and extends in a direction of the axis Z. A conductive cylindrical support 50 is provided on an outer periphery of the cylindrical support 48. The cylindrical support 50 extends from the bottom 12b of the processing container 12 toward the dielectric window 20 along the outer periphery of the cylindrical support 48. An annular exhaust path 51 is formed between the cylindrical support 50 and the sidewall 12a.

An annular baffle plate 52 having a plurality of through-holes formed in a thickness direction is provided on an upper portion of the exhaust path 51. The exhaust port 12h described above is provided below the baffle plate 52. An exhaust device 56, which includes, e.g., a vacuum pump such as a turbo molecular pump or an automatic pressure control valve, is connected to the exhaust port 12h via an exhaust pipe 54. The exhaust device 56 is capable of depressurizing the processing space S to a desired degree of vacuum.

The base 14a functions as a radio frequency electrode. A radio frequency power supply 58 for RF bias is electrically connected to the base 14a via a power feed rod 62 and a matching unit 60. The radio frequency power supply 58 supplies bias power of a predetermined frequency (for example, 13.56 MHz) suitable for controlling the energy of ions entering the substrate WP to the base 14a via the matching unit 60 and the power feed rod 62.

The matching unit 60 accommodates a matcher for matching between the impedance on the radio frequency power supply 58 and the impedance on the load side, such as an electrode, a plasma, and the processing container 12. A blocking capacitor for self-bias generation is included in the matcher. In addition, the radio frequency power supply 58, the matching unit 60, and the power feed rod 62 may be omitted when RF bias is not used.

The electrostatic chuck 14c is provided on an upper surface of the base 14a. The electrostatic chuck 14c attracts and holds the substrate WP by an electrostatic force. The electrostatic chuck 14c has a substantially disk-shaped outer shape, and includes an electrode 14d, an insulating film (dielectric film) 14e, and an insulating film (dielectric film) 14f. The electrostatic chuck 14c is disposed on the upper surface of the base 14a so that a central axis of the electrostatic chuck 14c substantially coincides with the axis Z. The electrode 14d of the electrostatic chuck 14c is formed of a conductive film and is provided between the insulating film 14e and the insulating film 14f. A direct current (DC) power supply 64 is electrically connected to the electrode 14d via a wire sheath 68 and a switch 66. The electrostatic chuck 14c is capable of attracting and holding the substrate WP on an upper surface by an electrostatic force generated by a DC voltage applied from the DC power supply 64. The upper surface of the electrostatic chuck 14c is a loading surface on which the substrate WP is loaded, and faces the processing space S. That is, the electrostatic chuck 14c is provided so that the upper surface, which is the loading surface, faces the processing space S. Further, an edge ring 14b is provided on the base 14a. The edge ring 14b is disposed to surround the substrate WP and the electrostatic chuck 14c. The edge ring 14b is also referred to as a “focus ring”.

A flow path 14g is provided in the interior of the base 14a. A coolant is supplied to the flow path 14g from a chiller unit (not illustrated) via a pipe 70. The coolant supplied to the flow path 14g is returned to the chiller unit via a pipe 72. The temperature of the base 14a is controlled by circulating the coolant whose temperature is controlled by the chiller unit, through the flow path 14g in the base 14a. By controlling the temperature of the base 14a, the temperature of the substrate WP on the electrostatic chuck 14c is controlled via the electrostatic chuck 14c on the base 14a.

Further, a pipe 74 is formed in the stage 14 to supply a heat transfer gas such as an He gas between the upper surface of the electrostatic chuck 14c and a back surface of the substrate WP.

The RF power supply 16 is coupled to the antenna 30 and is configured to generate a source RF signal (source RF power) for plasma generation via at least one impedance matching circuit. In one embodiment, the source RF signal has a frequency in a range of 3 MHz to 3,000 MHz. In one embodiment, the RF power supply 16 may be configured to generate a plurality of source RF signals having different frequencies. The generated one source RF signal, or the plurality of source RF signals are supplied to the antenna 30. In addition, as described above, the RF power supply 16 is an example of an electromagnetic wave generator that generates electromagnetic waves for plasma excitation to be supplied into the processing container 12, and is an example of a radio frequency power supply. Further, the antenna 30 is an example of an electromagnetic wave supplier that supplies electromagnetic waves into the processing container 12 via a dielectric. In addition, the source RF power is an example of power input to the antenna 30.

The antenna 30 includes one coil or a plurality of coils. In one embodiment, the antenna 30 may include an outer coil and an inner coil disposed coaxially. In this case, the RF power supply 16 may be connected to both the outer coil and the inner coil, or may be connected to either one of the outer coil and the inner coil. In the former case, the same RF generator in the RF power supply 16 may be connected to both the outer coil and the inner coil, or separate RF generators may be connected to the outer coil and the inner coil separately. In one embodiment, the antenna 30 is a planar coil and is formed in a substantially circular spiral shape (planar spiral shape). That is, the antenna 30 is wound in a loop shape. In addition, a magnetic field generated by the antenna 30 is oriented in the direction of the axis Z. Further, an opening of the antenna 30 may have any shape of a circular shape, an elliptical shape, or a polygonal shape (such as a rectangular shape or triangular shape). Furthermore, the antenna 30 is an example of a coil-shaped antenna.

Further, when the antenna 30 includes the outer coil and the inner coil, the outer coil functions as a primary coil to which the RF power supply 16 is connected. In one embodiment, the outer coil is a planar coil and is formed in a substantially circular spiral shape. The inner coil functions as a secondary coil that is inductively coupled to the primary coil. That is, the inner coil is not connected to the RF power supply 16. In one embodiment, the inner coil is a planar coil and is formed in a substantially circular ring shape. In one embodiment, the direction and magnitude of current flowing through the inner coil are controlled by connecting the inner coil to the variable capacitor and controlling a capacity of the variable capacitor. The outer coil and the inner coil may be disposed at the same height or at different heights. In one embodiment, the inner coil is disposed at a lower position than the outer coil.

A gas introducer is configured to introduce at least one processing gas from the gas supplier 38 into the processing space S. In one embodiment, the gas introduction includes the central gas injector (CGI) 13. The central gas injector 13 is disposed above the stage 14 and is attached to central openings formed in the dielectric window 20 and the cover 80. The central gas injector 13 includes at least one gas supply port 13a, at least one gas flow path 13b, and at least one gas introduction port 13c. The processing gas supplied to the gas supply port 13a passes through the gas flow path 13b and is introduced into the processing space S from the gas introduction port 13c, and is excited by electromagnetic waves supplied to the processing space S from the antenna 30 via the dielectric window 20. Thereby, the processing gas is plasmarized in the processing space S, and the substrate WP is processed by, ions and radicals contained in a plasma. Additionally, the gas introducer may include one or a plurality of side injectors (SGI) installed in one or a plurality of openings formed on the sidewall 12a in addition to or instead of the central gas injector 13.

The gas supplier 38 may include at least one gas source 38a and at least one flow-rate controller 38b. In one embodiment, the gas supplier 38 is configured to supply at least one processing gas from a corresponding gas source 38a to the gas introducer via a corresponding flow-rate controller 38b. Each flow-rate controller 38b may include, for example, a mass flow controller or a pressure-controlled flow-rate controller. Furthermore, the gas supplier 38 may include one or more flow-rate modulation devices that modulate or pulse a flow rate of at least one processing gas.

The cover 80 serves to prevent the leakage of electromagnetic waves from the antenna 30, and is provided at the upper end portion of the sidewall 12a to cover the dielectric window 20 and the antenna 30. The cover 80 includes metallic frame bodies 81 and 82. The frame body 81 constitutes an upper portion of the cover 80. The frame body 82 constitutes a sidewall of the cover 80. The frame bodies 81 and 82 are made of, for example, aluminum. A plurality of segments 85 and 89 to be described later are provided on inner surfaces 81a and 82a of the frame bodies 81 and 82.

Here, physical phenomena in a metallic cover for preventing the leakage of electromagnetic wave will be described. Physical phenomena when electromagnetic waves are irradiated to a metal include transmission, absorption, reflection, and scattering. Since transmission leads to electromagnetic wave leakage, and absorption causes power loss resulting in heat generation, so suppression using the metallic cover is required. Further, since reflection occurs on a flat surface and scattering occurs on an uneven surface, it is possible to control reflection with the metallic cover.

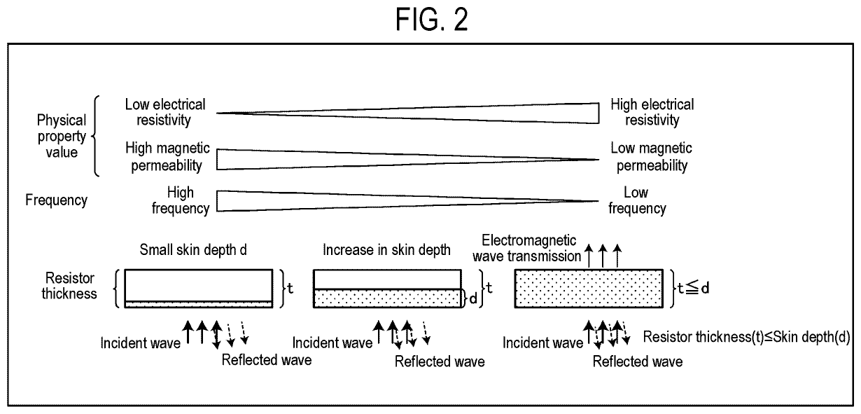

Next, transmission and absorption in the metallic cover will be described with reference to FIGS. 2 to 4. FIG. 2 is a diagram illustrating an exemplary relationship between resistor thickness, skin depth, and physical property values. In FIG. 2, a resistor is used as an example of the metallic cover, and a relationship between resistor thickness, skin depth, and physical property values is described. A skin depth d is expressed by the following Equation 1. In addition, the resistor includes a conductor and a resistive element, which are formed on a surface of a metallic frame body by, thermal spraying, printing, or affixation. Further, the resistor also includes, for example, a form in which ferrite-based particles are held by a binder. In addition, a conductor such as aluminum also has resistance value, so they may be treated as a resistor.

$$\begin{matrix}[ Equation 1 ] & \\ d = \sqrt{\frac{2 ρ}{ω μ}} & ( 1 )\end{matrix}$$

In Equation (1), “p” indicates electrical resistivity, “ω” indicates an angular frequency of electromagnetic waves, and “u” indicates magnetic permeability. As can be understood from FIG. 2 and Equation (1), the skin depth d decreases as the electrical resistivity ρ decreases, and increases as at least one of the magnetic permeability μ or the angular frequency ω decreases. For example, when the skin depth d is smaller than a resistor thickness t, incident waves are reflected by the resistor and is not transmitted. For example, in one or more of a case where the frequency of electromagnetic waves (angular frequency ω) decreases, a case where the magnetic permeability μ decreases, and a case where the electrical resistivity ρ increases, the skin depth d increases. For example, when the skin depth d is equal to or thicker than the resistor thickness t, incident waves transmit through the resistor, and electromagnetic wave leakage occurs along with the increased loss of electromagnetic waves. In addition, the magnetic permeability μ is expressed as a product of a permeability of vacuum μ₀=4π×10⁻⁷ H/m and a relative magnetic permeability μᵣ of the resistor.

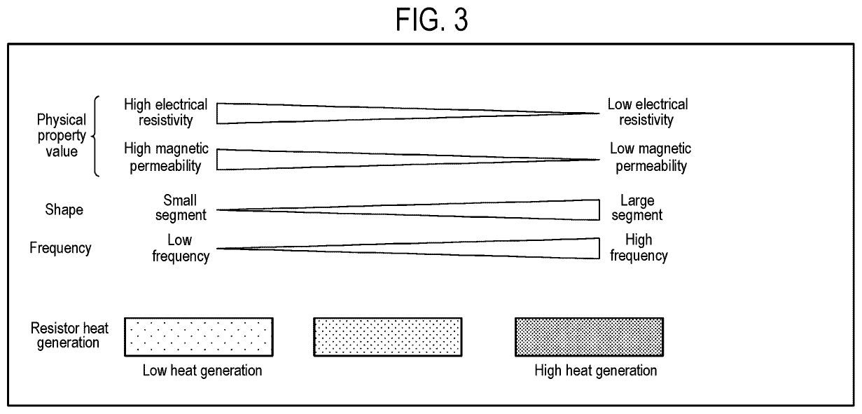

FIG. 3 is a diagram illustrating an exemplary relationship between heat generation, physical property values, and shape of a resistor. In FIG. 3, a resistor is used as an example of the metallic cover, and a relationship between heat generation of the resistor and physical property values is described. A power loss P corresponding to the heat generation of the resistor is expressed by the following Equation (2). In addition, the power loss P is an example of eddy current loss.

$$\begin{matrix}[ Equation 2 ] & \\ P = {a}^{4} \cdot \frac{{B}_{m}^{2}}{48} \sqrt{\frac{2 {ω}^{3}}{μ ρ}} \cdot {N}_{s e g} [ W ] & ( 2 )\end{matrix}$$

In Equation (2), “a” indicates a side dimension of polygonal segments with gaps therebetween, “Bₘ” indicates a saturation magnetic flux density, “ρ” indicates electrical resistivity, “ω” indicates an angular frequency of electromagnetic waves, “μ” indicates magnetic permeability, and “N_{seg}” indicates the number of segments. As can be understood from FIG. 3 and Equation (2), the power loss P increases as at least one of the electrical resistivity ρ or the magnetic permeability μ decreases, and increases as at least one of the side dimension a of the polygonal segments, the number of segments N_{seg}, or the angular frequency ω increases. For example, in one or more of a case where the electrical resistivity ρ increases, a case where the magnetic permeability μ decreases, a case where the side dimension a increases, a case where the number of segments N_{seg} increases, and a case where the frequency (angular frequency ω) of electromagnetic waves increases, the power loss P increases. That is, when the power loss P increases, the loss of electromagnetic waves increases and heat generation of the resistor increases.

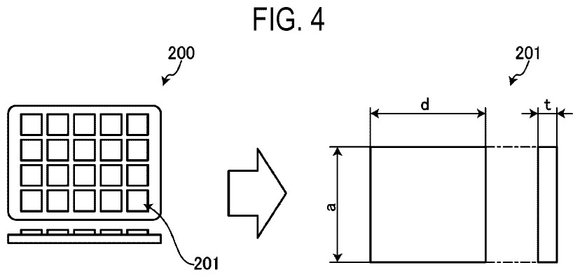

FIG. 4 is a diagram illustrating an exemplary segment. When a quadrilateral is used as a polygonal segment, as illustrated in FIG. 4, a surface of a member 200 is formed to include a plurality of segments 201. Each segment 201 is, for example, a quadrilateral having a side dimension a×a side dimension d, and has a thickness t (resistor thickness t). Here, absorption (heat generation) due to eddy currents in each segment 201, i.e., the power loss P, may be expressed by the following Equation (3).

$$\begin{matrix}[ Equation 3 ] & \\ P = \frac{a \cdot {t ( ω {B}_{m} )}^{2} \cdot {d}^{3}}{48 ρ} [ W ] & ( 3 )\end{matrix}$$

If the shape of the segment 201 is considered a square for simplification, it becomes the dimension a equals the dimension d, and Equation (3) may be expressed as the following Equation (4). In addition, in the following description, a square having a side dimension a may be expressed as □a or a□.

$$\begin{matrix}[ Equation 4 ] & \\ P = \frac{{a}^{4} \cdot {t ( ω {B}_{m} )}^{2}}{48 ρ} [ W ] & ( 4 )\end{matrix}$$

Furthermore, when Equation (1) is applied with the thickness t equals skin depth, the power loss P may be expressed by the following Equation (5). Further, the number of segments N_{seg} may be expressed by the following Equation (6).

$$\begin{matrix}[ Equation 5 ] & \\ P = \frac{{a}^{4} \cdot \sqrt{\frac{2 ρ}{ω μ}} {( ω {B}_{m} )}^{2}}{48 ρ} \cdot {N}_{s e g} [ W ] & ( 5 )\end{matrix}$$

$$\begin{matrix}[ Equation 6 ] & \\ {N}_{s e g} = {( L / a )}^{2} & ( 6 )\end{matrix}$$

In addition, “L” indicates a side dimension, for example, when the member 200 is formed in a square shape. Further, “L” indicates the dimension a, for example, when the number of segments N_{seg} is set to “1”. When Equation (5) becomes Equation (2), which expresses the power loss P.

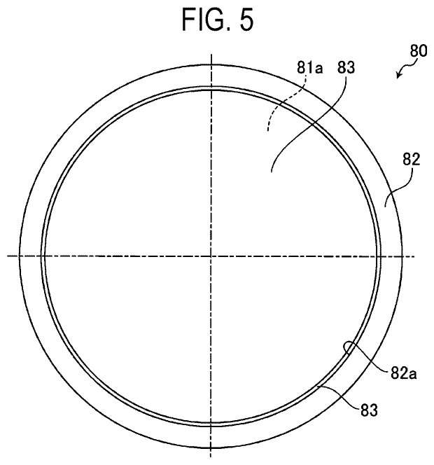

Next, a configuration example of a two-layer resistor film in the cover 80 will be described with reference to FIGS. 5 to 7. FIG. 5 is a plan view illustrating an exemplary configuration, as viewed from below, of a first layer of a two-layer resistor film in the cover according to the present embodiment. As illustrated in FIG. 5, an insulating layer 83 is formed on the inner surfaces 81a and 82a of the cover 80. The insulating layer 83 is, for example, a dielectric such as polyimide, FR4, and poly tetra fluoro ethylene (PTFE).

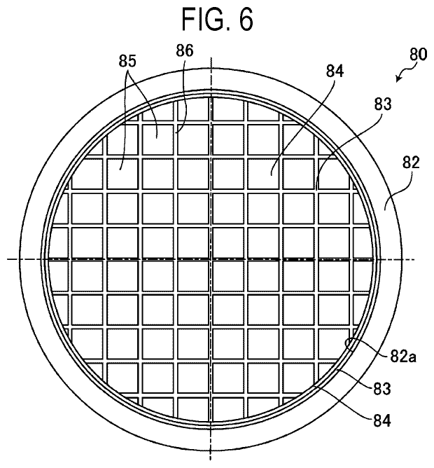

FIG. 6 is a plan view illustrating an exemplary configuration, as viewed from below, of a second layer of the two-layer resistor film in the cover according to the present embodiment. As illustrated in FIG. 6, the cover 80 includes a resistor layer 84 formed on the insulating layer 83. The resistor layer 84 includes a plurality of segments 85. Gaps 86 are provided between the plurality of segments 85. That is, the plurality of segments 85 have the gaps 86 between them and are configured to cover the inner surfaces 81a and 82a. In addition, in FIG. 6, for example, the segments 85 and the gaps 86 are arranged such that the center lines in the X-axis and Y-axis directions pass through the gaps 86.

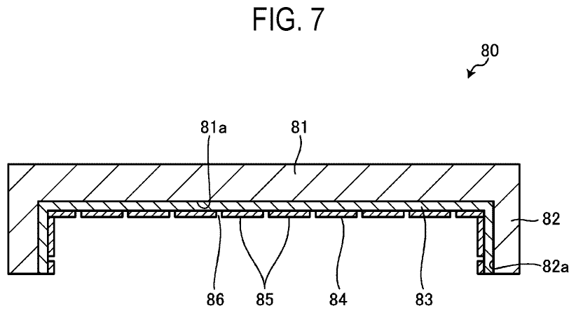

FIG. 7 is a cross-sectional view illustrating an exemplary cross-section of the cover according to the present embodiment. As illustrated in FIG. 7, in the cross-section of the cover 80, the insulating layer 83 and the resistor layer 84 are stacked sequentially on the inner surfaces 81a and 82a of the frame bodies 81 and 82. In addition, FIG. 7 illustrates a cross-section taken along a line that is slightly offset from the center line in the X-axis direction of FIG. 6 and passes through the plurality of segments 85 of the resistor layer 84 and the gaps 86 therebetween.

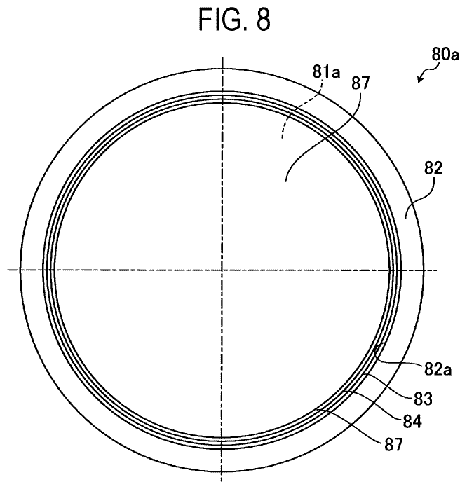

FIG. 8 is a plan view illustrating an exemplary configuration, as viewed from below, of a third layer of a four-layer resistor film in the cover according to the present embodiment. As illustrated in FIG. 8, a cover 80a has a four-layer resistor film structure in which an insulating layer and a resistor layer are further stacked on the two-layer resistor film illustrated in FIG. 6. An insulating layer 87 is further formed on the inner surfaces 81a and 82a of the cover 80a illustrated in FIG. 8. For example, the insulating layer 87 is, a dielectric such as polyimide, FR4, or PTFE.

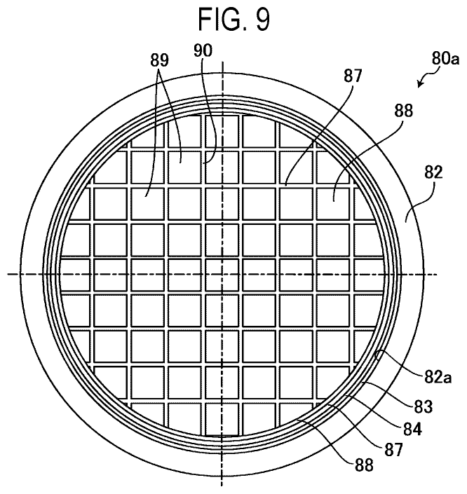

FIG. 9 is a plan view illustrating an exemplary configuration, as viewed from below, of a fourth layer of the four-layer resistor film in the cover according to the present embodiment. As illustrated in FIG. 9, the cover 80a includes a resistor layer 88 formed on the insulating layer 87. The resistor layer 88 includes a plurality of segments 89. Gaps 90 are provided between the plurality of segments 89. That is, the plurality of segments 89 have the gaps 90 between them and are configured to cover the inner surfaces 81a and 82a. In addition, in FIG. 9, for example, the segments 89 and the gaps 90 are arranged such that center lines in the X-axis and Y-axis direction through the plurality of segments 89.

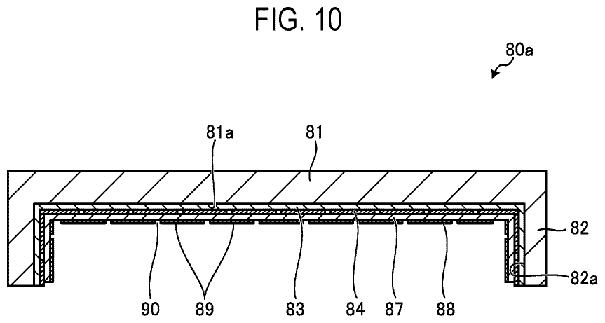

FIG. 10 is a cross-sectional view illustrating another exemplary cross-section of the cover according to the present embodiment. As illustrated in FIG. 10, in the cross-section of the cover 80a, the insulating layer 83, the resistor layer 84, the insulating layer 87 and the resistor layer 88 are stacked sequentially on the inner surfaces 81a and 82a of the frame bodies 81 and 82. In addition, FIG. 10 illustrates a cross-section taken along a line, that is slightly offset from the center line in the X-axis direction of FIG. 9 and passes through the plurality of segments 89 of the resistor layer 88 and the gaps 90 therebetween. That is, the plurality of segments 85 formed in the resistor layer 84 and the plurality of segments 89 formed in the resistor layer 88 are disposed at positions offset from each other in the X-axis direction and the Y-axis direction. By this arrangement, when viewed from below the cover 80a, the inner surfaces 81a and 82a of the frame bodies 81 and 82 are not visible in a high frequency sense.

Further, in the covers 80 and 80a, the plurality of segments 85 and 89 and gaps 86 and 90 are alternately arranged, for example, in the circumferential direction even at a connection portion of the frame bodies 81 and 82. By this arrangement, the covers 80 and 80a may prevent generation of eddy currents in the circumferential direction at the connection of the frame bodies 81 and 82.

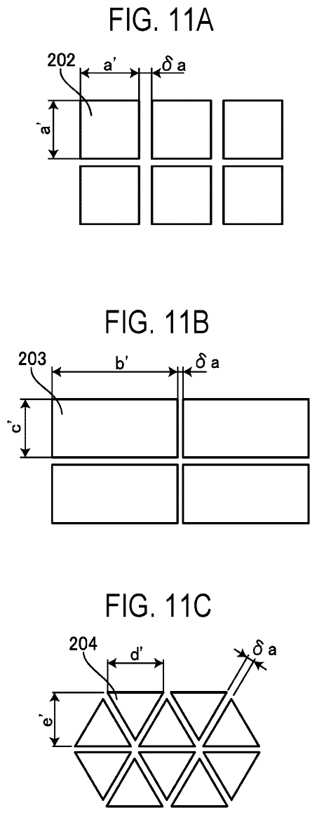

FIGS. 11A to 11C are diagrams illustrating exemplary arrangements of a plurality of segments according to the present embodiment. In FIGS. 11A to 11C, examples of a polygonal arrangement of a plurality of segments will be described. Segments 202 illustrated in FIG. 11A are squares each having a dimension a′× a dimension a′, with a gap δa between each of the segments 202. Segments 203 illustrated in FIG. 11B are rectangles each having a dimension b′×a dimension c′, with a gap δa between each of the segments 203. Segments 204 illustrated in FIG. 11C are triangles each having a side dimension d′× a height e′, with a gap δa between each of the segments 204. In FIGS. 11A to 11C, the segments 202 to 204 have a relationship of dimensions a′, b′, c′, d′, e′>>gap δa. In addition, when a gap δa increases, as the electromagnetic waves propagate through the gaps between the segments, the electromagnetic waves propagate along the side of the segment to generate eddy currents, or the electromagnetic waves propagate to the metal of the cover to generate eddy currents, thereby generating heat. The segments 202 to 204 are applicable to the segments 85 and 89, and as polygons applicable to the segments 85 and 89, polygons having eight or fewer sides.

In addition, heat generation due to power loss within an allowable range in the covers 80 and 80a may be cooled by providing a cooling structure such as a cooling water flow path, a heat sink, or a fan in the covers 80 and 80a. By cooling the covers 80 and 80a, a phase transition of ferromagnetism and paramagnetism in the metal of the covers 80 and 80a may be suppressed. That is, the Curie temperature countermeasures in the metal of the covers 80 and 80a may be taken.

As described above, the covers 80 and 80a include the metallic frame bodies 81 and 82 and the plurality of segments 85 and 89 provided on the inner surfaces 81a and 82a of the frame bodies. The plurality of segments 85 and 89 have the gaps 86 and 90 provided between them, respectively, and are configured to cover the inner surfaces 81a and 82a. Thereby, the covers 80 and 80a may increase power contributing to plasma generation by reducing eddy currents. Further, since the covers 80 and 80a may suppress heat generation due to eddy currents, a complicated cooling structure may be omitted. Further, as the plasma processing apparatus 1, the covers 80 and 80a and the antenna 30 may be approached, so that the plasma processing apparatus 1 may be downsized.

Further, a shape of each of the plurality of segments 85 and 89 is a polygon having eight or fewer sides, and it is desirable that a side dimension of the polygon is 100 mm or less. Further, in each of the plurality of segments 85 and 89, it is desirable that the side dimension of the polygon is 50 mm or less, and it is more desirable that the side dimension of the polygon is 30 mm or less. Further, in each of the plurality of segments 85 and 89, it is desirable that each of the gaps 86 and 90 has a dimension of one-tenth or less of the side dimension of the polygon.

Further, when the plurality of segments 85 and 89 are conductors, it is desirable that the insulating layers 83 and 87 be interposed between the pair of the frame bodies 81 and 82 and the plurality of segments 85 and 89, respectively. Further, when two or more layers of the plurality of segments 85 and 89 are provided, it is desirable that the plurality of segments 85 and 89 are arranged such that the gaps 86 in the first layer (resistor layer 84) and the gaps 90 in the second layer (resistor layer 88) are offset from each other.

Referring again to FIG. 1, the controller 11 includes a processor, a memory, and an input/output interface. The memory stores programs, process recipes and the like. The processor reads programs from the memory and executes the programs to collectively control each part of the apparatus main body 10 via the input/output interface based on the process recipes stored in the memory.

That is, the controller 11 processes computer-executable instructions that cause the plasma processing apparatus 1 to execute various steps described in the present disclosure. The controller 11 may be configured to control each element of the plasma processing apparatus 1 so as to execute various steps described herein. In one embodiment, a part or all of the controller 11 may be included in the apparatus main body 10. The controller 11 is implemented, for example, by a computer. The controller 11 may include a processing section, a storage section, and a communication interface. Functions realized by the processing section described in the disclosure may be implemented in circuitry or processing circuitry, including a general-purpose processor, a specific-purpose processor, integrated circuits, application specific integrated circuits (ASICs), a central processing unit (CPU), conventional circuitry, and/or combinations thereof, which are programmed to realize the functions described herein. The processor is regarded as circuitry or processing circuitry including transistors and other circuitry. The processor may be a programmed processor that executes programs stored in the storage section. These programs may be stored in advance in the storage section, or may be acquired via a non-transitory computer-readable medium when necessary. The acquired programs are stored in the storage section, and are read out and executed by the processing section. The medium may be any of various computer-readable storage media, or may be a communication line connected to the communication interface. The storage section may include a random access memory (RAM), a read only memory (ROM), a hard disk drive (HDD), a solid state drive (SSD), or combinations thereof. The communication interface may communicate between the apparatus main body 10 via a communication line such as a local area network (LAN). In the present disclosure, a circuit, a unit, and means are hardware programmed to realize the functions described herein, or hardware configured to execute the functions described herein. The hardware may be any hardware described in the present disclosure, or any hardware known to be programmed or configured to realize or execute the functions described herein. When such hardware is a processor regarded as a type of circuitry, the circuit, mean, or unit is a combination of hardware and software used to configure the hardware and/or the processor.

### [Setting of Segment Size]

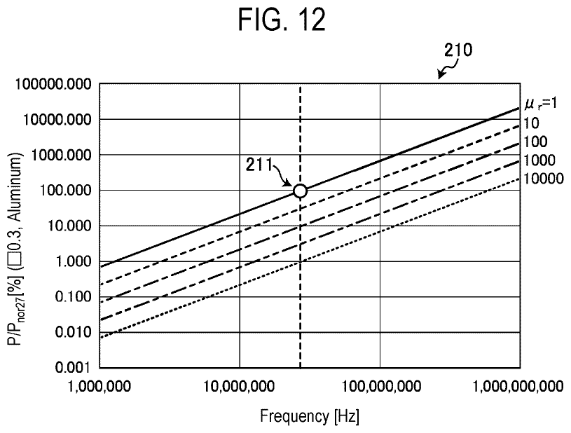

Next, the setting of the sizes of the segments 85 and 89 will be described with reference to FIGS. 12 to 23. FIG. 12 is a diagram illustrating an exemplary relationship between electromagnetic wave frequency and power loss. Graph 210 illustrated in FIG. 12 represents a relationship between frequency and power loss in a case where, as a reference 211, the frequency of electromagnetic waves is 27.12 MHz, the size of the segments 85 and 89 is a square having a side dimension of 0.3 m, and the material is aluminum. In addition, in the following description, a square having a side dimension of 0.3 m may be denoted in the form of □0.3.

In the reference 211, in the above Equation (2), the side dimension a=0.3 m, the angular frequency ω=2π×27.12×10⁶ rad/s, the relative magnetic permeability μᵣ=1, the electrical resistivity ρ=2.7×10⁻⁸ Ω·m, and N_{seg}=1, and the power loss in this case is denoted as Pₙₒᵣ₂₇. Further, in Graph 210, the power loss when the angular frequency ω and the relative magnetic permeability μᵣ are varied is denoted as P, and P/Pₙₒᵣ₂₇ is represented. From Graph 210, it can be understood that the power loss increases when the frequency of electromagnetic waves increases, and that the power loss decreases when the relative magnetic permeability μᵣ increases.

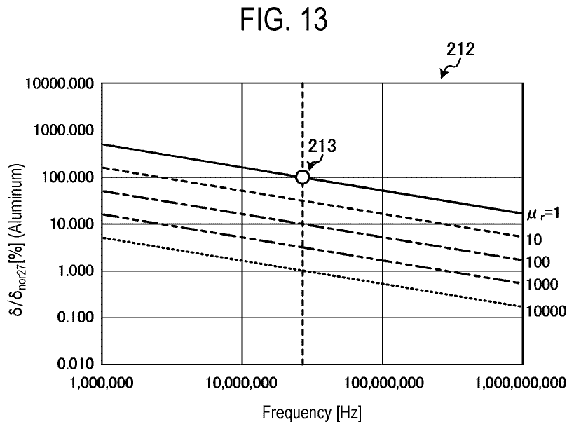

FIG. 13 is a diagram illustrating an exemplary a relationship between electromagnetic wave frequency and skin depth. Graph 212 illustrated in FIG. 13 represents a relationship between frequency and skin depth in a case where, as a reference 213, the frequency of electromagnetic waves is 27.12 MHz, the size of the segments 85 and 89 is □0.3, and the material is aluminum. In the reference 213, in the above Equation (1), the angular frequency ω=2π×27.12×10⁶ rad/s, the relative magnetic permeability μᵣ=1, and the electrical resistivity ρ=2.7×10^{-8 22}·m, and the skin depth d in Equation (1) in this case is denoted as δₙₒᵣ₂₇. Further, in Graph 212, the skin depth when the angular frequency ω and the relative magnetic permeability μᵣ are varied is denoted as δ, and δ/δₙₒᵣ₂₇ is represented. From Graph 212, it can be understood that the skin depth decreases when the frequency of electromagnetic waves increases, and that the skin depth decreases when the relative magnetic permeability μᵣ increases.

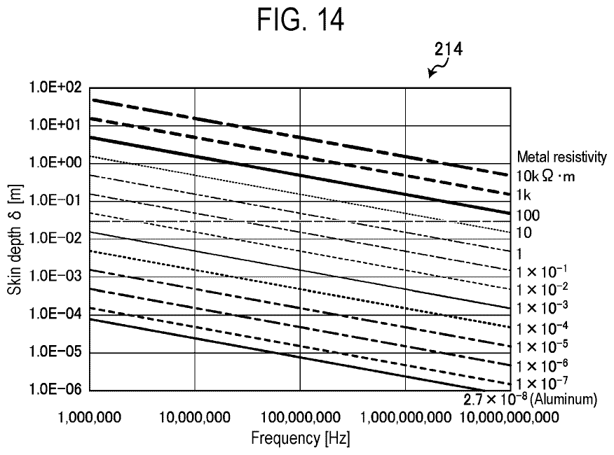

FIG. 14 is a diagram illustrating an exemplary relationship between physical property values and skin depth. Graph 214 illustrated in FIG. 14 represents a relationship between the metal resistivity (electrical resistivity) ρ as an example of the physical property values, the skin depth δ, and the frequency of electromagnetic waves. In addition, in the following description, when aluminum is used as the material of the resistor, the electrical resistivity ρ may also be referred to as the “metal resistivity ρ”. Further, the electrical resistivity ρ and the metal resistivity ρ may simply be referred to as the “resistivity ρ”. From Graph 214, it may be seen that the skin depth decreases as the frequency of electromagnetic waves increases, and that the skin depth decreases as the metal resistivity ρ decreases. Further, expressing the skin depth & as a function of the metal resistivity ρ, the relative magnetic permeability μᵣ, and the frequency f based on the above Equation (1) yields the following Equation (7).

$$\begin{matrix}[ Equation 7 ] & \\ δ ( ρ , {μ}_{r} , f ) = 503.29 \; 21 \times {ρ}^{0.5} \times {μ}_{r}^{- 0.5} \times {f}^{- 0.5} & ( 7 )\end{matrix}$$

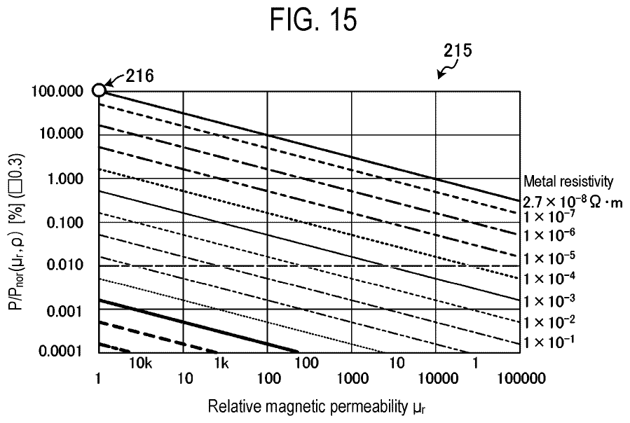

FIG. 15 is a diagram illustrating an exemplary relationship between physical property values and power loss. Graph 215 illustrated in FIG. 15 represents a relationship between the metal resistivity ρ as an example of the physical property values, the normalized power loss P/Pₙₒᵣ(P/Pₙₒᵣ(μᵣ, ρ, a)) and the relative magnetic permeability μᵣ. In addition, the vertical axis of Graph 215 represents the power loss P/Pₙₒᵣ(μᵣ, ρ) when a=0.3. A reference 216 corresponds to a case where, in the above Equation (2), the size of the segments 85 and 89 is 10.3 and the material is aluminum, that is, a case where the metal resistivity ρ=2.7×10⁻⁸ Ω·m, the relative magnetic permeability μᵣ=1, and N_{seg}=1. From Graph 215, it can be understood that the power loss decreases as the relative magnetic permeability μᵣ increases, and that the power loss also decreases as the metal resistivity ρ increases. Further, expressing the power loss (P/Pₙₒᵣ) as a function of the relative magnetic permeability μᵣ, the metal resistivity ρ, and the side dimension a of the segments 85 and 89 based on the above Equation (2) yields the following Equation (8). In addition, P/Pₙₒᵣ(μᵣ, ρ, a) may also be expressed as P (μᵣ, ρ, a)/Pₙₒᵣ. That is, since values of μᵣ, ρ, and a are substituted into Pₙₒᵣ, only P is a function of μᵣ, ρ, and a.

$$\begin{matrix}[ Equation 8 ] & \\ P / {P}_{n o r} = P / {P}_{n o r} ( {μ}_{r} , ρ , a ) = 1.82571 \times 1 {0}^{- 3} \times {ρ}^{- 0.5} \times {μ}_{r}^{- 0.5} \times {a}^{2} & ( 8 )\end{matrix}$$

Here, a case where the above Equations (7) and (8) are treated as equations expressing a relationship between the relative magnetic permeability μᵣ and physical property values will be considered. First, Equation (7) may be expressed as the following Equation (9). Further, by transforming Equation (9) into an equation expressing the relative magnetic permeability μᵣ, it may be expressed as the following Equation (10). Furthermore, if a condition that the skin depth δ is thinner than the resistor thickness t (δ<t) is given as a constraint, a relationship between the relative magnetic permeability μᵣ and the physical property values (the metal resistivity ρ, the resistor thickness t, and the frequency f) may be expressed by the following Equation (11). Further, Equation (11) may be expressed as the following Equation (12) by rounding off the second decimal place.

$$\begin{matrix}[ Equation 9 ] & \\ δ = 50 \; 3.2 \; 921 \sqrt{\frac{ρ}{{μ}_{r} f}} & ( 9 )\end{matrix}$$

$$\begin{matrix}[ Equation 10 ] & \\ {μ}_{r} = {( 503.2921 )}^{2} \cdot \frac{ρ}{{δ}^{2} f} = 2.53303 \times 1 {0}^{5} \cdot \frac{ρ}{{δ}^{2} f} & ( 10 )\end{matrix}$$

$$\begin{matrix}[ Equation 11 ] & \\ {μ}_{r} > 2.53303 \times 1 {0}^{5} \cdot \frac{ρ}{{t}^{2} f} & ( 11 )\end{matrix}$$

$$\begin{matrix}[ Equation 12 ] & \\ {μ}_{r} > 2.5 \times 1 {0}^{5} \cdot \frac{ρ}{{t}^{2} f} & ( 12 )\end{matrix}$$

Next, when the normalized power loss P/Pₙₒᵣ in Equation (8) is denoted as Pₙ, Equation (8) may be expressed as the following Equation (13). Further, by transforming Equation (13) into an equation expressing the relative magnetic permeability μᵣ, it may be expressed as the following Equation (14). Furthermore, if a condition that the normalized loss in the resistor is less than Pₙ% as a constraint, a relationship between the relative magnetic permeability μᵣ and the physical property values (the side dimension a of the segments 85 and 89, the metal resistivity ρ, and the normalized power loss Pₙ) may be expressed by the following Equation (15). Further, Equation (15) may be expressed as the following Equation (16) by rounding off the second decimal place.

$$\begin{matrix}[ Equation 13 ] & \\ Pn = \frac{1.82571 \times 1 {0}^{- 3} \times {a}^{2}}{\sqrt{ρ \cdot {μ}_{r}}} & ( 13 )\end{matrix}$$

$$\begin{matrix}[ Equation 14 ] & \\ {μ}_{r} = \frac{{( 1.82571 \times 1 {0}^{- 3} \times {a}^{2} )}^{2}}{ρ \cdot {Pn}^{2}} = \frac{3.33322 \times 1 {0}^{- 6} \times {a}^{4}}{ρ \cdot {Pn}^{2}} & ( 14 )\end{matrix}$$

$$\begin{matrix}[ Equation 15 ] & \\ {μ}_{r} > \frac{3.33322 \times 1 {0}^{- 6} \times {a}^{4}}{ρ \cdot {Pn}^{2}} & ( 15 )\end{matrix}$$

$$\begin{matrix}[ Equation 16 ] & \\ {μ}_{r} > \frac{3.3 \times 1 {0}^{- 6} \times {a}^{4}}{ρ \cdot {Pn}^{2}} & ( 16 )\end{matrix}$$

Furthermore, setting of the size of the segments 85 and 89 is performed by adding a constraint condition that the relative magnetic permeability in the following Equation (17) is 1 or more (μᵣ≥1).

$$\begin{matrix}[ Equation 17 ] & \\ {μ}_{r} ≧ 1 & ( 17 )\end{matrix}$$

That is, when the plurality of segments 85 and 89 are resistors, the relative magnetic permeability μᵣ and the resistivity ρ of the resistors are configured to satisfy Equations (12), (16), and (17). However, in Equation (12), “t” indicates the thickness of each of the plurality of segments 85 and 89, and “f” indicates the frequency of radio frequency power supplied to the antenna 30. Further, in Equation (16), “a” represents the side dimension of each of the plurality of segments 85 and 89, and “Pₙ” represents the normalized power loss. Further, when the plurality of segments 85 and 89 are resistors, it is desirable that the resistors contain a ferrite-based magnetic material. Further, it is desirable that the thickness of each of the plurality of segments 85 and 89 be thicker than the skin depth of the radio frequency power supplied to the antenna 30.

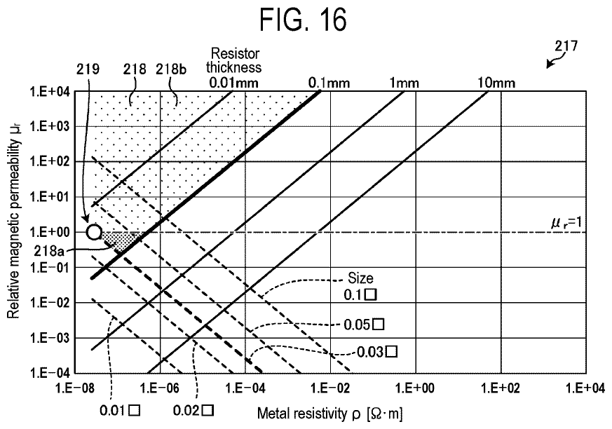

FIG. 16 is a diagram illustrating an exemplary setting of physical property values and segment size. Graph 217 illustrated in FIG. 16 represents a relationship between the dimension a, the resistor thickness t, the relative magnetic permeability μᵣ, and the metal resistivity ρ for the segments 85 and 89 when the frequency of electromagnetic waves is 13.56 MHz and a target loss (power loss) is 1%. In addition, the size of the segments 85 and 89 may also be denoted as a size a corresponding to the dimension a. Further, the power loss may simply be referred to as “loss”. As represented in Graph 217, a region 218 satisfying conditions of the size a≤□0.03 (a square having a side length of 0.03 m) and the resistor thickness t≥0.1 mm (0.1 mm thickness) is a region in which the loss is 1% or less. Further, ranges of the relative magnetic permeability μᵣ and the metal resistivity ρ, which are the physical property values of the region 218b, excluding the region 218a from the region 218, are determined under the condition of the relative magnetic permeability μᵣ≥1. In addition, the region 218a is difficult to apply in nature. Since the region 218b includes physical property values 219 of aluminum, aluminum having the size a≤□0.03 and the resistor thickness t≥0.1 mm (0.1 mm thickness) may be used as the segments 85 and 89. In addition, although other metals may also be used as the segments 85 and 89, when the frame bodies 81 and 82 are made of aluminum, an insulating layer is required between the frame bodies 81 and 82 and the segments 85 and 89. On the other hand, when the size a is set to □0.05 and the resistor thickness t is set to be >0.1 mm, the physical property values 219 of aluminum deviate from the region in which the loss is 1% or less at the frequency of 13.56 MHz. Accordingly, it can be understood that aluminum having the size a=□0.05 and the resistor thickness t≥0.1 mm (0.1 mm thickness) may not be used as the segments 85 and 89.

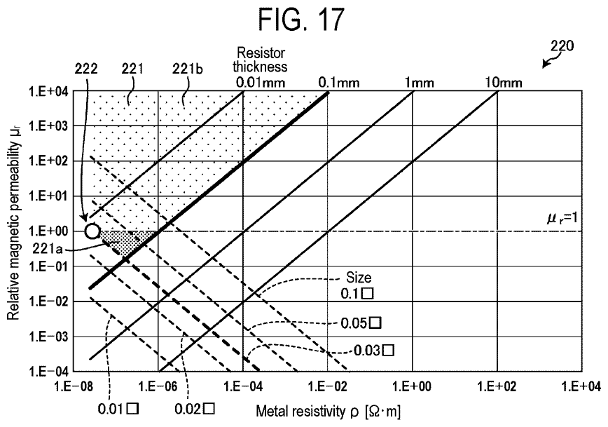

FIG. 17 is a diagram illustrating another exemplary setting of physical property values and segment size. Graph 220 illustrated in FIG. 17 represents a relationship between the size a, the resistor thickness t, the relative magnetic permeability μᵣ, and the metal resistivity ρ for the segments 85 and 89 when the frequency of electromagnetic waves is 27.12 MHz and a target loss is 1%. As represented in Graph 220, a region 221 satisfying conditions of the size a≤□0.03 and the resistor thickness t≥0.1 mm (0.1 mm thickness) is a region in which the loss is 1% or less. Further, ranges of the relative magnetic permeability μᵣ and the metal resistivity ρ, which are the physical property values of the region 221b, excluding the region 221a from the region 221, are determined under the condition of the relative magnetic permeability μᵣ≥1. In addition, the region 221a is difficult to apply in nature. Since the region 221b includes physical property values 222 of aluminum, aluminum having the size a≤□0.03 and the resistor thickness t≥0.1 mm (0.1 mm thickness) may be used as the segments 85 and 89. In addition, although other metals may also be used as the segments 85 and 89, when the frame bodies 81 and 82 are made of aluminum, an insulating layer is required between the frame bodies 81 and 82 and the segments 85 and 89. On the other hand, when the size a is set to □0.05 and the resistor thickness t is set to be >0.1 mm, the physical property values 219 of aluminum deviate from the region in which the loss is 1% or less at the frequency of 27.12 MHz. Accordingly, it can be understood that aluminum having the dimension a=□0.05 and the resistor thickness t≥0.1 mm (0.1 mm thickness) may not be used as the segments 85 and 89.

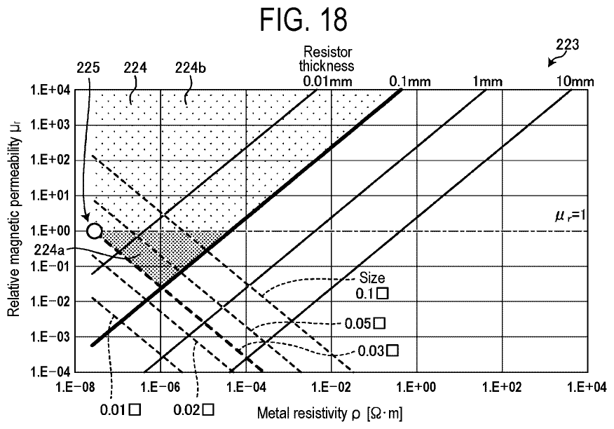

FIG. 18 is a diagram illustrating another exemplary setting of physical property values and segment size. Graph 223 illustrated in FIG. 18 represents a relationship between the size a, the resistor thickness t, the relative magnetic permeability μᵣ, and the metal resistivity ρ for the segments 85 and 89 when the frequency of electromagnetic waves is 1,000 MHz and a target loss is 1%. As represented in Graph 223, a region 224 satisfying conditions of the size a≤□0.03 and the resistor thickness t≥0.1 mm (0.1 mm thickness) is a region in which the loss is 1% or less. Further, ranges of the relative magnetic permeability μᵣ and the metal resistivity ρ, which are the physical property values of the region 224b, excluding the region 224a from the region 224, are determined under the condition of the relative magnetic permeability μᵣ≥1. In addition, the region 224a is difficult to apply in nature. Since the region 224b includes physical property values 225 of aluminum, it may appear that aluminum having the size a≤□0.03 and the resistor thickness t≥0.1 mm (0.1 mm thickness) may be used as the segments 85 and 89. However, Graph 223 does not take into account differences in loss due to frequency. In addition, when a size a is set to □0.05 and the resistor thickness t is set to be >0.1 mm, the physical property values 225 of aluminum deviate from the region in which the loss is 1% or less at the frequency of 1,000 MHz. Accordingly, it can be understood that aluminum having the dimension a=□0.05 and the resistor thickness t≥0.1 mm (0.1 mm thickness) may not be used as the segments 85 and 89.

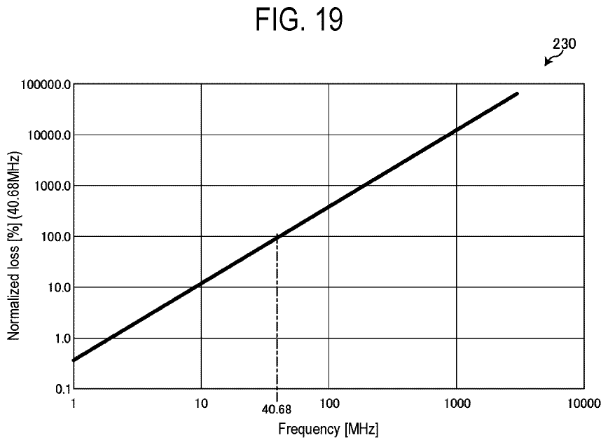

FIG. 19 is a diagram illustrating an exemplary normalized loss at a specific frequency. Graph 230 illustrated in FIG. 19 represents the normalized loss at a frequency of 40.68 MHz, and it can be understood that the loss increases as the frequency increases. For example, with a microwave band of 1,000 MHz, a loss of more than 100 times that of 40.68 MHz occurs. That is, as the frequency increases, it is required to reduce the proportion of loss.

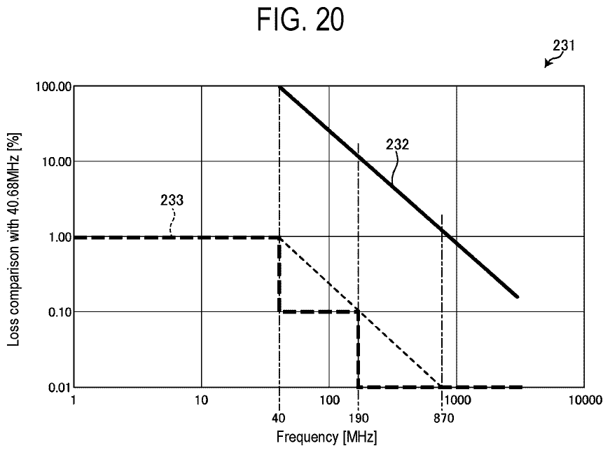

FIG. 20 is a diagram illustrating an exemplary loss setting for each frequency. Graph 231 illustrated in FIG. 20 represents a loss equivalent to that at 40.68 MHz and a target loss to be set. Graph 232 represents the proportion of the loss equivalent to that at 40.68 MHz at frequencies exceeding 40.68 MHz. For example, a loss of 1% at 870 MHz is equivalent to a loss of 0.01% at 40.68 MHz. Accordingly, the target loss is set to be 1% up to 40 MHz, 0.1% from 40 MHz to 190 MHz, and 0.01% at 190 MHz or more, for example, as represented in Graph 233. That is, the target loss is 0.01% at 870 MHz or more.

That is, each of the plurality of segments 85 and 89 is configured to have a dimension and thickness such that eddy current loss due to electromagnetic coupling with the antenna 30 is 1% or less of the power input to the antenna 30.

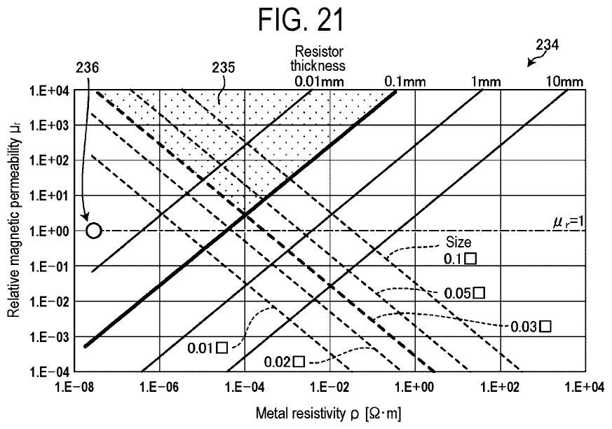

FIG. 21 is a diagram illustrating another exemplary setting of physical property values and segment size. As illustrated in FIG. 21, Graph 234, which takes into account differences in loss due to frequency, represents a relationship between the size a, the resistor thickness t, the relative magnetic permeability μᵣ, and the metal resistivity ρ as the segments 85 and 89 when the frequency of electromagnetic waves is 1,000 MHz and a target loss is 0.01%. As represented in Graph 234, a region 235 satisfying conditions of the size a≤10.03 and the resistor thickness t≥0.1 mm (0.1 mm thickness) is a region in which the loss is 0.01% or less. It can be understood that the region 235 does not include physical property values 236 of aluminum, and therefore, a metal such as aluminum may not be used as the segments 85 and 89. In addition, when the size a is set to □0.05 and the resistor thickness t is set to be >0.1 mm, the region 235 becomes narrower, and therefore, a metal such as aluminum may not be used as the segments 85 and 89.

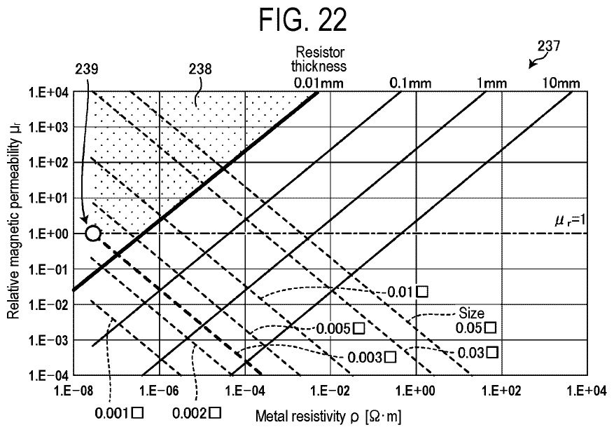

FIG. 22 is a diagram illustrating another exemplary setting of physical property values and segment size. Graph 237 illustrated in FIG. 22 represents a relationship between the size a, the resistor thickness t, the relative magnetic permeability μᵣ, and the metal resistivity ρ for the segments 85 and 89 when the frequency of electromagnetic waves is 1,000 MHz and a target loss is 0.01%. As represented in Graph 237, a region 238 satisfying conditions of the size a≤□0.003 and the resistor thickness t≥0.01 mm (0.01 mm thickness) is a region in which the loss is 0.01% or less. In addition, in Graph 237, a region in which the relative magnetic permeability μᵣ<1 has already been excluded from the region 238. That is, the region 238 is a range of the relative magnetic permeability μᵣ and the metal resistivity ρ satisfying the above conditions. Since the region 238 includes physical property values 239 of aluminum, aluminum having the size a≤□0.003 and the resistor thickness t≥0.01 mm (0.01 mm thickness) may be used as the segments 85 and 89. In addition, aluminum having the size a≤□0.003 and the resistor thickness t≥0.1 mm (0.1 mm thickness) also satisfies the conditions, and therefore, may also be used. Further, although other metals may also be used as the segments 85 and 89, when the frame bodies 81 and 82 are made of aluminum, an insulating layer is required between the frame bodies 81 and 82 and the segments 85 and 89.

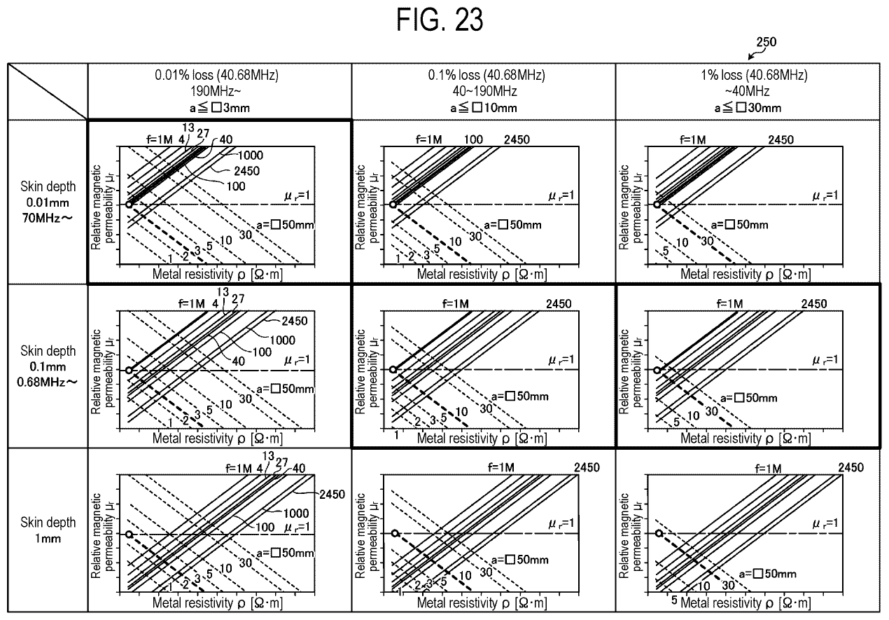

FIG. 23 is a diagram illustrating an exemplary application range based on loss setting and segment size. Table 250 illustrated in FIG. 23 summarizes application ranges based on loss setting for each electromagnetic wave frequency f, the size of the segments 85 and 89, and the skin depth. In Table 250, combinations of skin depth settings are listed for the size a corresponding to the target loss represented in Graph 233 of FIG. 20, where the skin depth minimizes the resistor thickness t for preventing electromagnetic wave leakage from the segment 85 and 89. In addition, in each graph, the solid lines indicating respective frequencies f are lines connecting the relative magnetic permeability μᵣ and the metal resistivity ρ at which the skin depths at the respective frequencies f become 0.01 mm, 0.1 mm, and 1 mm, respectively. Further, in each graph, the dotted lines indicating respective sizes a are lines connecting the relative magnetic permeability μᵣ and the metal resistivity ρ at which the loss (relative to 40.68 MHz) at the respective sizes a become 0.01%, 0.1%, and 1%, respectively.

As illustrated in Table 250, when the loss is 0.01% (relative to 40.68 MHz), the frequency f is 190 MHz or more, and the size a is ≤□3 mm (=□0.003), the skin depth is 0.01 mm or less at a frequency of 70 MHz or more. From this, when the frequency f is 190 MHz or more, by setting the segments 85 and 89 to the size a≤□3 mm, the skin depth of 0.01 mm or less, and the resistor thickness t of 0.01 mm or more, the loss of 0.01% (relative to 40.68 MHz) and electromagnetic wave leakage may be prevented.

As illustrated in Table 250, when the loss is 0.1% (relative to 40.68 MHz), the frequency f is 40 MHz or more and less than 190 MHz, the size a is ≤□10 mm (□0.01), and a frequency range of 40 MHz or more and less than 70 MHz, the skin depth exceeds 0.01 mm, and when the resistor thickness t is set to 0.1 mm, electromagnetic waves may leak and thus may not be applied. From this, when the frequency f is 40 MHz or more and less than 190 MHz, the segments 85 and 89 have a size a≤□10 mm, and the skin depth of 0.1 mm or less, and by setting the resistor thickness t to 0.1 mm or more, the loss of 0.1% (relative to 40.68 MHz) and electromagnetic wave leakage may be prevented.

As illustrated in Table 250, when the loss is 1% (relative to 40.68 MHz), the frequency f is less than 40 MHz, and the size a is ≤□30 mm (□0.03), the skin depth exceeds 0.01 mm in a frequency range of 0.68 MHz or more and less than 40 MHz, and when the resistor thickness t is set to 0.01 mm, electromagnetic waves are leaked and cannot be applied. From this, when the frequency f is 0.68 MHz or more and less than 40 MHz, the segments 85 and 89 have a size a≤30 mm and the skin depth of 0.1 mm or less, and by setting the resistor thickness t to 0.1 mm or more, the loss of 1% (relative to 40.68 MHz) and electromagnetic wave leakage may be prevented.

### Structural Example of Cover

Next, an example of a structure and manufacturing method of the covers 80 and 80a will be described. When the segments 85 and 89 are formed on the inner surfaces 81a and 82a of the covers 80 and 80a, they may be formed, for example, by applying, printing, or affixing the insulating layers 83 and 87 and the resistor layers 84 and 88. Further, the segments 85 and 89 may be formed by machining them from the frame bodies 81 and 82 of the covers 80 and 80a. In this case, the thickness of the segments 85 and 89 may be 10 mm (10 mm thickness). That is, the segments 85 and 89 may be formed using a metal such as aluminum or copper, or may be formed using the resistor layers 84 and 88 in which ferrite-based particles (for example, iron oxide, ferrite, and nickel-cobalt) are held by a binder. For example, when the resistor layers 84 and 88 are used, the relative magnetic permeability μᵣ and the electrical resistivity ρ may be set by adjusting the composition of the resistor layers 84 and 88 (for example, the dispersion ratio of ferrite particles and an insulating binder, and the material and particle size of ferrite particles). Further, stainless steel may be used as the frame bodies 81 and 82. Furthermore, the size a and the thickness t of the segments 85 and 89 may be changed according to the frequency of electromagnetic waves used in the plasma processing apparatus 1.

For example, when the frame bodies 81 and 82 of the covers 80 and 80a are made of aluminum, the sizes of the segments 85 and 89 may be set as follows according to the frequency of electromagnetic waves. When the frequency of electromagnetic waves is 190 MHz or more, the segments 85 and 89 may be set to have the size a of □1 mm to □3 mm, the thickness t of 0.01 mm to 10 mm, and a width of the gaps 86 and 90 of 0.001 mm to 0.1 mm. In addition, the width of the gaps 86 and 90 may be 1/10 or less of the thickness t of the segments 85 and 89, or 1/10 or less of the size a.

When the frequency of electromagnetic waves is 70 MHz or more and less than 190 MHz, the segments 85 and 89 may be set to have the size a of □1 mm to □10 mm, the thickness t of 0.01 mm to 10 mm, and a width of the gaps 86 and 90 of 0.001 mm to 0.1 mm. In addition, the width of the gaps 86 and 90 may be 1/10 or less of the thickness t of the segments 85 and 89, or 1/10 or less of the size a.

When the frequency of electromagnetic waves is less than 70 MHz, the segments 85 and 89 may be set to have the size a of □1 mm to □30 mm, the thickness t of 0.1 mm to 10 mm, and a width of the gaps 86 and 90 of 0.001 mm to 0.1 mm.

In a method of manufacturing the covers 80 and 80a, for example, the insulating layer 83 is thermally sprayed onto the inner surfaces 81a and 82a of the frame bodies 81 and 82, the resistor layer 84 is printed with a dispense or the like and fired to form the segments 85. In a case of forming the segments 89, further, on the fired resistor layer 84 (the segments 85), the insulating layer 87 is sprayed, the resistor layer 88 is printed with the dispense or the like, and fired to form the segments 89. The segments 85 and 89 corresponding to this manufacturing method have the size a≥□1 mm, the thickness t=10 μm to 1 mm, and the gap width ≥0.1 mm (approximately equal to a/10).

Further, in a method of manufacturing the covers 80 and 80a, for example, the insulating layer 83 is affixed onto the inner surfaces 81a and 82a of the frame bodies 81 and 82, the resistor layer 84 is printed with a dispense or the like and fired to form the segments 85. In a case of forming the segments 89, further, the insulating layer 87 is affixed onto the fired resistor layer 84 (the segments 85), and the resistor layer 88 is printed with a dispense or the like and fired to form the segments 89. The segments 85 and 89 corresponding to this manufacturing method have the size a≥□1 mm, the thickness t=10 μm to 1 mm, and the gap width ≥0.1 mm (approximately equal to a/10).

Further, in a method of manufacturing the covers 80 and 80a, for example, a single-layer copper clad laminate (CCL) is affixed to the inner surfaces 81a and 82a of the frame bodies 81 and 82. Next, a copper foil of the single-layer CCL is pattern-cut using, e.g., a substrate milling cutter to form the gaps 86, thereby forming the segments 85. In a case of forming the segments 89, further, a single-layer CCL is affixed onto the segments 85. Next, the copper foil of the single-layer CCL is pattern-cut using, e.g., a substrate milling cutter to form the gaps 90, thereby forming the segments 89. In addition, a two-layer CCL may be used instead of the single-layer CCL. The segments 85 and 89 corresponding to this manufacturing method have the size a≥□1 mm, the thickness t=10 μm to 1 mm, and the gap width ≥0.1 mm (approximately equal to a/10).

Further, in a method of manufacturing the covers 80 and 80a, for example, the insulating layer 83 is affixed onto the inner surfaces 81a and 82a of the frame bodies 81 and 82, and the resistor layer 84 is affixed thereto. Next, the resistor layer 84 is pattern-cut using, e.g., a substrate milling cutter to form the gaps 86, thereby forming the segments 85. In a case of forming the segments 89, the insulating layer 87 is further affixed onto the segments 85. Next, the resistor layer 88 is pattern-cut using, e.g., a substrate milling cutter to form the gaps 90, thereby forming the segments 89. The segments 85 and 89 corresponding to this manufacturing method have the size a≥□1 mm, the thickness t=10 μm to 10 mm, and the gap width ≥0.1 mm (approximately equal to a/10).

Further, in a method of manufacturing the covers 80 and 80a, for example, the gaps 86 are formed in a copper foil of a single-layer CCL by photolithography and etching, thereby forming the segments 85. Next, the single-layer CCL in which the segments 85 have been formed is affixed onto the inner surfaces 81a and 82a of the frame bodies 81 and 82. In addition, in a case of forming the segments 89, before affixing to the inner surfaces 81a and 82a, an additional single-layer CCL is further affixed onto the segments 85. Next, the gaps 90 are formed in the copper foil of the affixed single-layer CCL by photolithography and etching, thereby forming the segments 89. Next, a stack of the single-layer CCLs, which forms the segments 85 and 89, is affixed to the inner surfaces 81a and 82a of the frame bodies 81 and 82. The segments 85 and 89 corresponding to this manufacturing method have the size a≥□1 mm, the thickness t=10 μm to 0.01 mm, and the gap width ≥0.01 mm (approximately equal to a/10).

As described above, according to the present embodiment, a cover (covers 80 and 80a) serves to prevent electromagnetic wave leakage from a coil-shaped antenna (antenna 30) provided in the plasma processing apparatus 1, the cover includes a metallic frame body (frame bodies 81 and 82) and a plurality of segments (segments 85 and 89) provided on an inner surface (inner surfaces 81a and 82a) of the frame body. The plurality of segments are configured to cover the inner surface with gaps (gaps 86 and 90) between each of the plurality of segments. As a result, the covers 80 and 80a may reduce eddy currents and increase power contributing to plasma generation.

Further, according to the present embodiment, each of the plurality of segments is configured to have dimension and a thickness that an eddy current loss due to electromagnetic coupling with the coil-shaped antenna is 1% or less of power input to the coil-shaped antenna. As a result, the covers 80 and 80a may prevent electromagnetic wave leakage and reduce eddy currents to increase power contributing to plasma generation.

Further, according to the present embodiment, a shape of each of the plurality of segments is a polygon having eight or fewer corners, and a dimension of one side of the polygon is 100 mm or less. As a result, the covers 80 and 80a may prevent electromagnetic wave leakage and reduce eddy currents to increase power contributing to plasma generation within a range that satisfies conditions of the relative magnetic permeability μᵣ and resistivity ρ of the plurality of segments.

Further, according to the present embodiment, each of the plurality of segments has a dimension that is 1/10 or less of the dimension of one side of the polygon. As a result, the covers 80 and 80a may prevent heat generation due to eddy currents.

Further, according to the present embodiment, when the plurality of segments are conductors, an insulating layer (insulating layers 83 and 87) is interposed between the frame bodies and the plurality of segments. As a result, the covers 80 and 80a may block electrical paths of eddy currents.

Further, according to the present embodiment, the dimension of one side of the polygon of each of the plurality of segments is 30 mm or less. As a result, the plurality of segments 85 and 89 may use metal at a frequency of 40 MHz or less.

Further, according to the present embodiment, the relative magnetic permeability μᵣ and resistivity ρ of the plurality of segments are configured to satisfy Equations (12), (16) and (17). In Equation (12), “t” indicates the thickness of each of the plurality of segments, and “f” indicates the frequency of radio frequency power supplied to the coil-shaped antenna. In Equation (16), “a” indicates the dimension of one side of each of the plurality of segments, and “Pₙ” indicates normalized power loss. As a result, the covers 80 and 80a may prevent electromagnetic wave leakage and reduce eddy currents to increase power contributing to plasma generation within a range in which the relative magnetic permeability μᵣ and resistivity ρ of a resistor satisfy prescribed conditions.

Further, according to the present embodiment, each of the dimension of one side of the polygon of each of the plurality of segments is 50 mm or less. As a result, the covers 80 and 80a may prevent electromagnetic wave leakage and reduce eddy currents to increase power contributing to plasma generation within a range in which the relative magnetic permeability μᵣ and resistivity ρ of a resistor satisfy prescribed conditions.

Further, according to the present embodiment, when two or more layers of the plurality of segments are provided, the plurality of segments are arranged that the gaps 86 of the first layer (resistor layer 84) and gaps 90 of the second layer (resistor layer 88) are offset from each other. As a result, the cover 80a may further prevent electromagnetic wave leakage from the gaps 86 of the plurality of segments 85.

Further, according to the present embodiment, the plurality of segments include a ferrite-based magnetic material. As a result, the plurality of segments 85 and 89 may adjust conditions of relative magnetic permeability μᵣ and resistivity ρ.

Further, according to the present embodiment, the thickness of each of the plurality of segments is thicker than the skin depth of radio frequency power supplied to the coil-shaped antenna. As a result, the covers 80 and 80a may prevent leakage of radio frequency power supplied to the coil-shaped antenna and reduce eddy currents to increase power contributing to plasma generation.

Further, according to the present embodiment, the plasma processing apparatus 1 includes the processing container 12, the coil-shaped antenna, and the cover. The processing container 12 is configured to have a space for plasma generation (processing space S). The coil-shaped antenna is configured to generate electromagnetic waves for plasma excitation to be supplied into the processing container 12. The cover is disposed on the processing container 12 to cover the coil-shaped antenna, and is configured to include a metallic frame body and a plurality of segments provided on an inner surface of the frame body, to prevent electromagnetic wave leakage from the coil-shaped antenna. Further, the plurality of segments are configured to cover the inner surface with gaps provided between each of the plurality of segments. As a result, the covers 80 and 80a may reduce eddy currents and increase power contributing to plasma generation. In addition, since the plasma processing apparatus 1 may approach the covers 80 and 80a and the antenna 30, the plasma processing apparatus 1 may be miniaturized

The embodiments disclosed herein should be considered to be exemplary and not limitative in all respects. The above embodiments may be omitted, substituted, or modified in various ways without departing from the scope of the appended claims and their gist.

Further, although the above-described embodiments have described the covers 80 and 80a that cover the antenna 30, the application range of the plurality of segments 85 and 89 is not limited thereto. For example, the plurality of segments 85 and 89 may be provided on an inner surface of an electromagnetic wave shield, in places where electromagnetic shielding is required, such as the interior of an electronic device or in a Magnetic Resonance Imaging (MRI) room.

In addition, the present disclosure may also adopt the following configurations.

(1)

A cover that prevents electromagnetic wave leakage from a coil-shaped antenna provided in a plasma processing apparatus, the cover including:
a metallic frame body; and
a plurality of segments provided on an inner surface of the frame body,
wherein the plurality of segments are configured to cover the inner surface with a gap between each of the plurality of segments.
   (2)

The cover of (1), wherein each of the plurality of segments is configured to have a dimension and a thickness such that an eddy current loss due to electromagnetic coupling with the coil-shaped antenna is 1% or less of power input to the coil-shaped antenna.

(3)

The cover of (2), wherein a shape of each of the plurality of segments is a polygon having eight or fewer corners, and a dimension of one side of the polygon is 100 mm or less.

(4)

The cover of (3), wherein the gap between each of the plurality of segments has a dimension that is 1/10 or less of the dimension of one side of the polygon.

(5)

The cover of (3) or (4), wherein, when the plurality of segments are conductors, an insulating layer is interposed between the frame body and the plurality of segments.

(6)

The cover of (3), wherein the dimension of one side of the polygon is 30 mm or less.

(7)

The cover in any of (1) to (6), wherein a relative magnetic permeability μᵣ and resistivity ρ of the plurality of segments are configured to satisfy the following Equations 18-20:

$$\begin{matrix}[ Equation 18 ] & \\ {μ}_{r} > 2.5 \times 1 {0}^{5} \cdot \frac{ρ}{{t}^{2} f} & ( 18 )\end{matrix}$$

$$\begin{matrix}[ Equation 19 ] & \\ {μ}_{r} > \frac{3.3 \times 1 {0}^{- 6} \times {a}^{4}}{ρ \cdot {Pn}^{2}} & ( 19 )\end{matrix}$$

$$\begin{matrix}[ Equation 20 ] & \\ {μ}_{r} ≧ 1 & ( 20 )\end{matrix}$$

wherein, in Equation 18, “t” indicates a thickness of each of the plurality of segments, and “f” indicates a frequency of radio frequency power supplied to the coil-shaped antenna, and wherein, in Equation 19, “a” indicates a dimension of one side of each of the plurality of segments, and “Pₙ” indicates a normalized power loss.
(8)

The cover of (7), wherein a shape of each of the plurality of segments is a polygon having eight or fewer corners, and a dimension of one side of the polygon is 50 mm or less.

(9)

The cover of any one of (1) to (8), wherein, when two or more layers of the plurality of segments are provided, the plurality of segments are arranged such that a gap between each of the plurality of segments of a first layer and a gap between each of the plurality of segments of a second layer are offset from each other.

(10)

The cover of any one of (1) to (9), wherein the plurality of segments include a ferrite-based magnetic material.

(11)

The cover of any one of (2) to (10), wherein the thickness of each of the plurality of segments is thicker than a skin depth of radio frequency supplied to the coil-shaped antenna.

(12)

A plasma processing apparatus including:
a processing container configured to have a space for plasma generation;
a coil-shaped antenna configured to generate electromagnetic waves of plasma excitation to be supplied into the processing container; and
a cover disposed on the processing container to cover the coil-shaped antenna, and configured to include a metallic frame body and a plurality of segments provided on an inner surface of the frame body, to prevent electromagnetic wave leakage from the coil-shaped antenna,
wherein the plurality of segments are configured to cover the inner surface with a gap between each of the plurality of segments.

According to the present disclosure, it is possible to reduce eddy currents and increase power contributing to plasma generation.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A cover that prevents electromagnetic wave leakage from a coil-shaped antenna provided in a plasma processing apparatus, the cover comprising:
a metallic frame body; and
a plurality of segments provided on an inner surface of the frame body,
wherein the plurality of segments are configured to cover the inner surface with a gap between each of the plurality of segments.

2. The cover of claim 1, wherein each of the plurality of segments is configured to have a dimension and a thickness such that an eddy current loss due to electromagnetic coupling with the coil-shaped antenna is 1% or less of power input to the coil-shaped antenna.

3. The cover of claim 2, wherein a shape of each of the plurality of segments is a polygon having eight or fewer corners, and a dimension of one side of the polygon is 100 mm or less.

4. The cover of claim 3, wherein the gap between each of the plurality of segments has a dimension that is 1/10 or less of the dimension of one side of the polygon.

5. The cover of claim 4, wherein a relative magnetic permeability μᵣ and resistivity ρ of the plurality of segments are configured to satisfy the following Equations (1) to (3):
$$\begin{matrix}[ Equation 1 ] & \\ {μ}_{r} > 2.5 \times 1 {0}^{5} \cdot \frac{ρ}{{t}^{2} f} & ( 1 )\end{matrix}$$
$$\begin{matrix}[ Equation 2 ] & \\ {μ}_{r} > \frac{3.3 \times 1 {0}^{- 6} \times {a}^{4}}{ρ \cdot {Pn}^{2}} & ( 2 )\end{matrix}$$
$$\begin{matrix}[ Equation 3 ] & \\ {μ}_{r} ≧ 1 , & ( 3 )\end{matrix}$$
wherein, in Equation (1), “t” indicates a thickness of each of the plurality of segments, and “f” indicates a frequency of radio frequency power supplied to the coil-shaped antenna, and
wherein, in Equation (2), “a” indicates a dimension of one side of each of the plurality of segments, and “Pₙ” indicates a normalized power loss.

6. The cover of claim 5, wherein the shape of each of the plurality of segments is the polygon having eight or fewer corners, and the dimension of one side of the polygon is 50 mm or less.

7. The cover of claim 3, wherein, when the plurality of segments are conductors, an insulating layer is interposed between the frame body and the plurality of segments.

8. The cover of claim 3, wherein the dimension of one side of the polygon is 30 mm or less.

9. The cover of claim 1, wherein a relative magnetic permeability μᵣ and resistivity ρ of the plurality of segments are configured to satisfy the following Equations (1) to (3):
$$\begin{matrix}[ Equation 1 ] & \\ {μ}_{r} > 2.5 \times 1 {0}^{5} \cdot \frac{ρ}{{t}^{2} f} & ( 1 )\end{matrix}$$
$$\begin{matrix}[ Equation 2 ] & \\ {μ}_{r} > \frac{3.3 \times 1 {0}^{- 6} \times {a}^{4}}{ρ \cdot {Pn}^{2}} & ( 2 )\end{matrix}$$
$$\begin{matrix}[ Equation 3 ] & \\ {μ}_{r} ≧ 1 , & ( 3 )\end{matrix}$$
wherein, in Equation (1), “t” indicates a thickness of each of the plurality of segments, and “f” indicates a frequency of radio frequency power supplied to the coil-shaped antenna, and
wherein, in Equation (2), “a” indicates a dimension of one side of each of the plurality of segments, and “Pₙ” indicates a normalized power loss.

10. The cover of claim 1, wherein, when two or more layers of the plurality of segments are provided, the plurality of segments are arranged such that a gap between each of the plurality of segments of a first layer and a gap between each of the plurality of segments of a second layer are offset from each other.

11. The cover of claim 1, wherein the plurality of segments include a ferrite-based magnetic material.

12. The cover of claim 2, wherein the thickness of each of the plurality of segments is thicker than a skin depth of radio frequency power supplied to the coil-shaped antenna.

13. A plasma processing apparatus comprising:
a processing container configured to have a space for plasma generation;
a coil-shaped antenna configured to generate electromagnetic waves for plasma excitation to be supplied into the processing container; and
a cover disposed on the processing container to cover the coil-shaped antenna, and configured to include a metallic frame body and a plurality of segments provided on an inner surface of the frame body, to prevent electromagnetic wave leakage from the coil-shaped antenna,
wherein the plurality of segments are configured to cover the inner surface with a gap between each of the plurality of segments.
